(19) United States
(12) Patent Application Publication
(10) Pub. No.: US 2023/0274993 A1
(43) Pub. Date: Aug. 31, 2023

(54) FABRICATION PROCESS FOR PROTECTING CIRCUIT COMPONENTS

(71) Applicant: TEXAS INSTRUMENTS INCORPORATED, Dallas, TX (US)

(72) Inventors: Anindya PODDAR, SUNNYVALE, CA (US); Amin SIJELMASSI, DALLAS, TX (US); Hau NGUYEN, SAN JOSE, CA (US); Kashyap MOHAN, IRVING, TX (US)

(21) Appl. No.: 17/683,253

(22) Filed: Feb. 28, 2022

(51) Int. Cl. H01L 23/31; H01L 23/04

(52) U.S. Cl. CPC H01L 23/3121; H01L 23/04

(57) ABSTRACT

One example includes a method for fabricating an integrated circuit (IC) device. The method includes fabricating a semiconductor die comprising an IC. The method also includes patterning a film over a portion of the first surface of the semiconductor die. The method also includes attaching a second surface of the semiconductor die opposite the first surface to a substrate. The method further includes depositing molding material over the semiconductor die to cover at least the first surface of the semiconductor die.

### TECHNICAL FIELD

This description relates generally to chip fabrication systems, and more particularly to a fabrication process for protecting circuit components.

### BACKGROUND

Integrated circuit (IC) packages have long been implemented in computer devices for providing increasingly compact circuits in computer products. Some ICs can be implemented for specialty applications that can require very specific and/or very precise outputs (e.g., analog outputs and/or high-frequency digital outputs). Such precision components can be highly subject to environmental considerations that can degrade performance of such components. As an example, mechanical stresses on the package can be conferred upon the precision components, such as based on contact of the precision components with molding material (e.g., epoxy) that is provided to fill gaps in the IC package. Thermal expansion/contraction and/or physical forces exhibited upon the molding material can be transferred to the precision components, resulting in a larger margin of error of the outputs of the precision components than can be required for proper operation of the precision components.

### SUMMARY

One example includes a method for fabricating an integrated circuit (IC) device. The method includes fabricating a semiconductor die comprising an IC. The method also includes patterning a film over a portion of the first surface of the semiconductor die. The method also includes attaching a second surface of the semiconductor die opposite the first surface to a substrate. The method further includes depositing molding material over the semiconductor die to cover at least the first surface of the semiconductor die.

Another example described herein includes an IC package. The device includes a semiconductor die that includes an IC. The device also includes a film patterned over a portion of the first surface of the semiconductor die. The device also includes a substrate coupled to a second surface of the semiconductor die opposite the first surface. The device further includes molding material covering at least the first surface of the semiconductor die.

Another example described herein includes an IC package. The device includes a semiconductor die that includes an IC. The IC comprising precision components arranged proximal to a first surface of the semiconductor die. The device also includes a photo-patternable polymer film photo-patterned over a portion of the first surface of the semiconductor die, the portion of the first surface of the semiconductor die overlying the precision components. The device also includes a substrate coupled to a second surface of the semiconductor die opposite the first surface. The device further includes molding material covering at least the first surface of the semiconductor die.

### BRIEF DESCRIPTION OF THE DRAWINGS

FIG. 1 is an example block diagram of an integrated circuit package.

FIG. 2 is an example of an integrated circuit package.

FIG. 3 is an example of a first fabrication step.

FIG. 4 is an example of a second fabrication step.

FIG. 5 is an example of a third fabrication step.

FIG. 6 is an example of a fourth fabrication step.

FIG. 7 is another example of an integrated circuit package.

FIG. 8 is another example of an integrated circuit package.

FIG. 9 is an example a method for fabricating an integrated circuit.

### DETAILED DESCRIPTION

This description relates generally to chip fabrication systems, and more particularly to a fabrication process for protecting circuit components. As an example, the protected circuit components can correspond to precision components. As described herein, the term “precision components” describes circuit components that are a part of the associated integrated circuit (IC) for which highly accurate and/or specific amplitudes of voltages and/or currents are provided, or that implement very high frequency switching. Therefore, as described herein, precision components can be particularly vulnerable to mechanical stresses that can degrade the amplitudes of the voltages and/or currents or can deleteriously affect the switching frequency of the precision components therein. The fabrication process provides for protecting precision components on a semiconductor die in an integrated circuit (IC) package from mechanical stresses that can be transferred through a molding material. The IC package includes the semiconductor die comprising the precision components fabricated from conventional semiconductor device fabrication processes. The precision components can be fabricated in the semiconductor die to be proximal to a first surface of semiconductor die (e.g., on the first surface).

The IC package also includes a film that is patterned over a portion of the first surface of the semiconductor die, such that the film overlays the precision components. As an example, the film can correspond to any of a variety of photo-patternable polymer films, such as any of a variety of SU-8 materials or polyimide materials. The IC package can be coupled to a substrate (e.g., via a die-attach adhesive material) via a second surface of the semiconductor die that is opposite the first surface. The IC package can further include a molding material that can cover at least the first surface of the semiconductor die, such as to fill voids between the IC package and an outer package. As an example, the material from which the film is formed can be non-adhesive with respect to the molding material, such that the molding material can delaminate with respect to the film, forming an air gap at the interface between the molding material and the film. As a result, a discontinuity is created in the mechanical stress transfer path resulting in isolation of the stress on the precision components from the molding material.

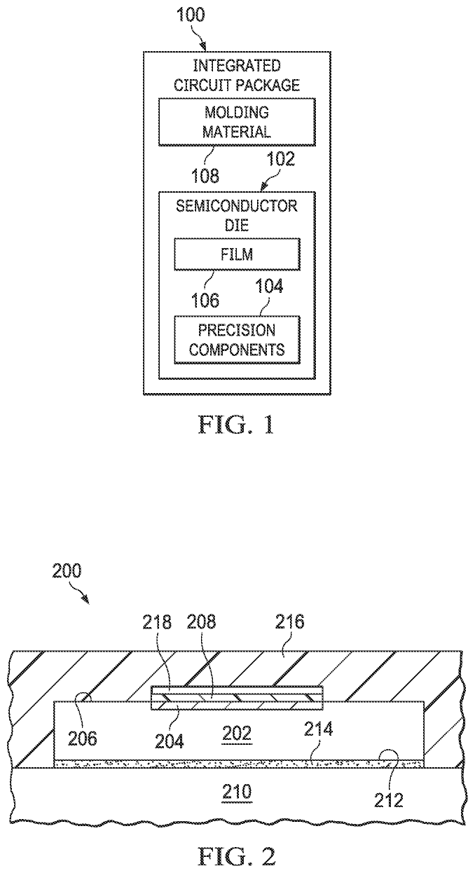

FIG. 1 is an example block diagram of an integrated circuit (IC) package 100. The IC package 100 can be implemented in any of a variety of applications that require precision operation (e.g., precision analog values and/or high-frequency digital applications). In the example of FIG. 1, the IC package 100 includes the semiconductor die 102 that can be fabricated from any of a variety of conventional semiconductor fabrication processes. The semiconductor die 102 includes precision components 104 that can be arranged proximal to a first surface of semiconductor die 102. As an example, the precision components 104 can be arranged on or at the first surface of the semiconductor die 102.

The IC package 100 also includes a film 106 that can be patterned over a portion of the first surface of the semiconductor die 102, such that the film 106 overlays the precision components 104. As an example, the film 106 can correspond to any of a variety of photo-patternable polymer films, such as any of a variety of SU-8 materials or polyimide materials. The IC package 100 further includes a molding material 108 that can cover at least the first surface of the semiconductor die 102. For example, the molding material 108 can be any of a variety of epoxy or polymer materials that can fill at least a portion of the interior of the IC package 100. As an example, the molding material 108 can fill voids between the components of the IC package 100 and the interior of a chip package. As described herein, the material from which the film 106 is formed can be non-adhesive with respect to the molding material 108. Therefore, the molding material 108 can delaminate with respect to the film 106 to provide an air gap between the molding material and the film 106. As a result, a discontinuity is created in the mechanical stress transfer path resulting in isolation of the stress on the precision components 104 from the molding material 108.

Such a fabrication process of delaminating the molding material 108 from the surface of the semiconductor die 102 (e.g., from the surface of the precision components 104) can provide for simple fabrication process that mitigates mechanical stresses on the precision materials. As opposed to other solutions provided in typical fabrication processes, the fabrication process described herein is less costly and results in a smaller form-factor IC package. For example, typical IC packages that implement a glob of flexible material (e.g., a synthetic rubber material) that surrounds the semiconductor die can result in a large form-factor IC package to accommodate the large volume of the flexible material. As another example, typical IC packages that implement a silicon cap provided on a standoff from the semiconductor die can involve a more complicated and costly fabrication process. Therefore, because the fabrication process described herein involves merely patterning a film material, the fabrication process for the IC package 100 can be much less complicated and expensive, and can result in a smaller form-factor IC chip.

FIG. 2 is an example diagram of an IC package 200. The IC package 200 can be implemented in any of a variety of applications that require precision operation (e.g., precision analog values and/or high-frequency digital applications). The IC package 200 can correspond to the IC package 100 in the example of FIG. 1. Therefore, reference is to be made to the example of FIG. 1 in the following description of FIG. 2.

The IC package 200 includes the semiconductor die 202 that can be fabricated from any of a variety of conventional semiconductor fabrication processes. The semiconductor die 202 includes precision components 204. In the example of FIG. 2, the precision components 204 are fabricated at a first surface 206 of the semiconductor die 202. The IC package 200 also includes a film 208 patterned over the portion of the first surface 206 of the semiconductor die 202 on which the precision components 204 are formed. Therefore, the film 208 overlays the precision components 204. As an example, the film 208 can correspond to any of a variety of photo-patternable polymer films, such as any of a variety of SU-8 materials or polyimide materials.

The IC package 200 also includes a substrate 210 to which the semiconductor die 202 is coupled. The substrate 210 can correspond to any of a variety of dielectric substrate materials (e.g., SiO₂). The substrate 210 is demonstrated as attached to a second surface 212 of the semiconductor die 202, with the second surface 212 being opposite the first surface 206. An adhesive material 214 (e.g., a die-attach material) can be used to couple the semiconductor die 202 to the substrate 210.

The IC package 200 further includes a molding material 216 that can cover at least the first surface 206 of the semiconductor die 202. As an example, the molding material 216 can fill voids between the components of the IC package 200 and the interior of a chip package (not shown in the example of FIG. 2). As described herein, the material from which the film 208 is formed can be non-adhesive with respect to the molding material 216. Therefore, the molding material 216 can be delaminated with respect to the film 208. In the example of FIG. 2, the delamination is demonstrated as an air gap 218 between the film 208 and the molding material 216. The air gap 218 is not depicted to scale in the example of FIG. 2. As a result, mechanical stresses on the precision components 204, such as being provided through the molding material 216, can be mitigated based on the air-gap 218 between the molding material 216 and the precision components 204.

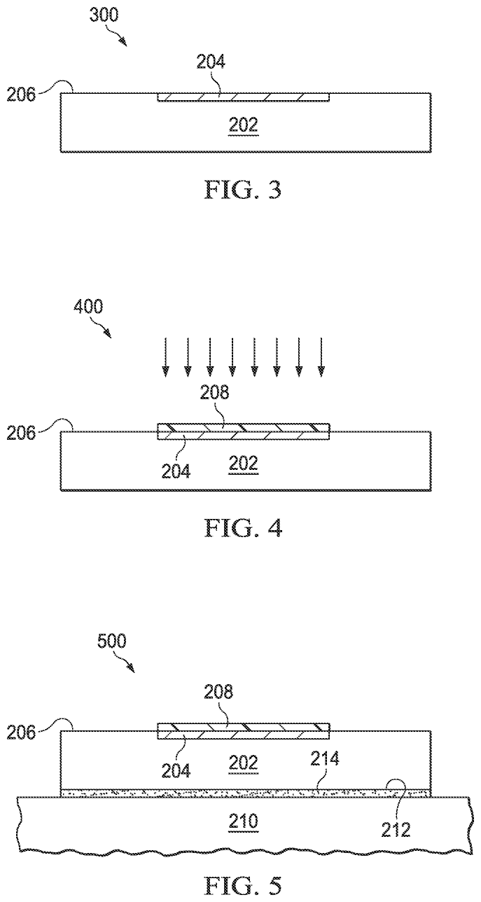

FIGS. 3-6 demonstrate fabrication steps for fabricating the IC package 200 in the example of FIG. 2. Therefore, like reference numbers are used in the examples of FIGS. 3-6 as provided in FIG. 2, and reference to FIG. 2 is to be made in the following examples of FIGS. 3-6.

FIG. 3 is an example of a first fabrication step 300. In the first fabrication step 300, the semiconductor die 202 is fabricated from any of a variety of conventional semiconductor fabrication processes. As described above, the fabrication of the semiconductor die 202 includes fabricating precision components 204 proximal to the first surface 206. As described above, in the examples of FIGS. 2 and 3, the precision components 204 are fabricated at the first surface 206 of the semiconductor die 202, and are thus exposed at the first surface of the semiconductor die 202.

FIG. 4 is an example of a second fabrication step 400. In the second fabrication step 400, a film 208 is patterned over the portion of the first surface 206 of the semiconductor die 202. In the example of FIG. 4, the film 208 is patterned over the portion of the first surface 206 on which the precision components 204 are fabricated. Therefore, the film 208 overlays the precision components 204. As an example, the film 208 can be patterned based on a photo-patterning process. The film 208 can correspond to any of a variety of photo-patternable polymer films, such as any of a variety of SU-8 materials or polyimide materials. The film 208 can exhibit a non-adhesive property with respect to epoxy-type materials that constitute the molding material 216.

FIG. 5 is an example of a third fabrication step 500. In the third fabrication step 500, the semiconductor die 202 is coupled to the substrate 210 via the adhesive material 214 (e.g., a die-attach material). The substrate 210 is demonstrated as attached to the second surface 212 of the semiconductor die 202 opposite the first surface 206.

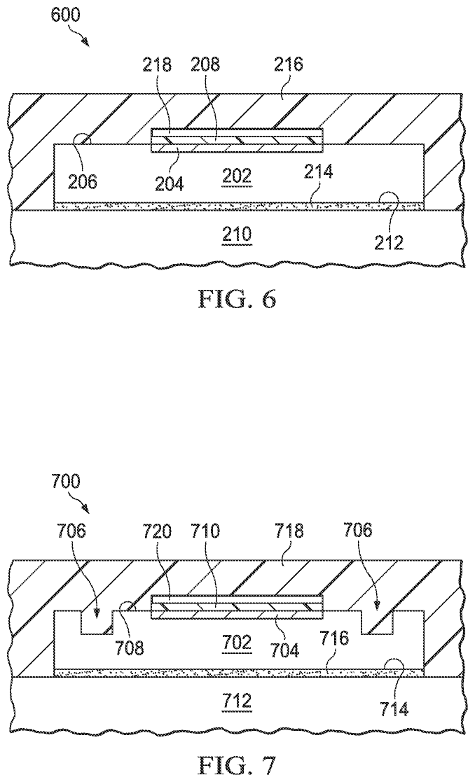

FIG. 6 is an example of a fourth fabrication step 600. In the fourth fabrication step 600, the molding material 216 is provided over the semiconductor die 202, and thus also over the film 208. As an example, the molding material 216 can be provided via an injection molding process. The molding material 216 is therefore provided over at least the first surface 206 of the semiconductor die 202. Therefore, based on the failure of the molding material 216 to adhere to the film 208, the air gap 218 is formed between the film 208 and the molding material 216. Accordingly, the air gap 218 can mitigate mechanical stresses on the precision components 204 in response to mechanical forces applied through the molding material 216 or thermal effects of the molding material 216.

FIG. 7 is another example of an IC package 700. The IC package 700 can be implemented in any of a variety of applications that require precision operation (e.g., precision analog values and/or high-frequency digital applications). The IC package 700 can correspond to the IC package 100 in the example of FIG. 1. Therefore, reference is to be made to the example of FIG. 1 in the following description of FIG. 7.

The IC package 700 includes the semiconductor die 702 that can be fabricated from any of a variety of conventional semiconductor fabrication processes. The semiconductor die 702 includes precision components 704, and further includes at least one trench 706 etched into the semiconductor die 702. The trench(es) 706 can be fabricated in any of a variety of ways, such as a continuous moat (e.g., rectangular), or multiple separate parallel and/or orthogonal trenches. In the example of FIG. 7, the trench(es) 706 at least partially surround the precision components 704. The precision components 704 and the trench(es) 706 are fabricated at a first surface 708 of the semiconductor die 702. Therefore, the trench(es) 706 can provide a degree of mechanical stress mitigation of the precision components 704. The IC package 700 also includes a film 710 patterned over the portion of the first surface 708 of the semiconductor die 702 on which the precision components 704 are formed. Therefore, the film 710 overlays the precision components 704. As an example, the film 710 can correspond to any of a variety of photo-patternable polymer films, such as any of a variety of SU-8 materials or polyimide materials.

The IC package 700 also includes a substrate 712 to which the semiconductor die 702 is coupled. The substrate 712 can correspond to a metal material frame that can provide connections to ground and to pins of the completed IC chip, such that portions of the substrate can extend from the completed IC chip. The substrate 712 is demonstrated as attached to a second surface 714 of the semiconductor die 702, with the second surface 714 being opposite the first surface 708. An adhesive material 716 (e.g., a die-attach material) can be used to couple the semiconductor die 702 to the substrate 712.

The IC package 700 further includes a molding material 718 that can cover at least the first surface 708 of the semiconductor die 702. As an example, the molding material 718 can fill voids between the components of the IC package 700 and the interior of a chip package (not shown in the example of FIG. 7). As described herein, the material from which the film 710 is formed can be non-adhesive with respect to the molding material 718. Therefore, the molding material 718 can be delaminated with respect to the film 710. In the example of FIG. 7, the delamination is demonstrated as an air gap 720 between the film 710 and the molding material 718. As a result, mechanical stresses on the precision components 704, such as being provided through the molding material 718, can be mitigated based on the air gap 720 between the molding material 718 and the precision components 704, as well as the trench(es) 706.

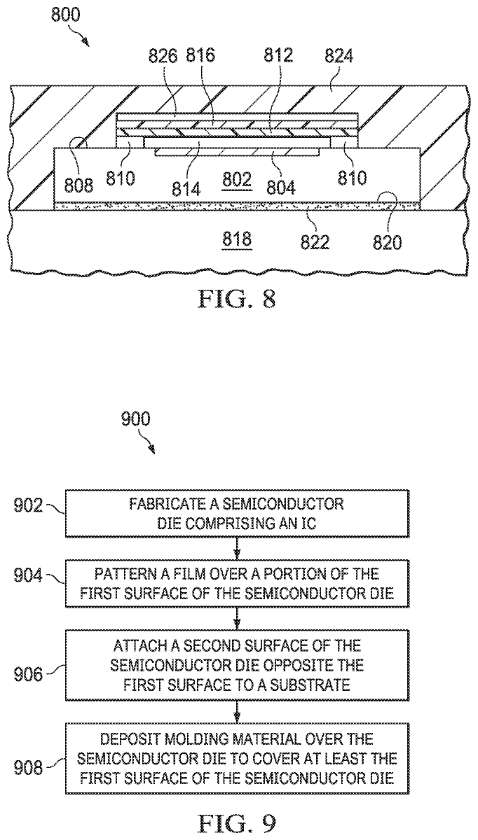

FIG. 8 is another example of an IC package 800. The IC package 800 can be implemented in any of a variety of applications that require precision operation (e.g., precision analog values and/or high-frequency digital applications). The IC package 800 can correspond to the IC package 100 in the example of FIG. 1. Therefore, reference is to be made to the example of FIG. 1 in the following description of FIG. 8.

The IC package 800 includes the semiconductor die 802 that can be fabricated from any of a variety of conventional semiconductor fabrication processes. The semiconductor die 802 includes precision components 804. In the example of FIG. 8, the precision components 804 are fabricated at a first surface 808 of the semiconductor die 802. The IC package 800 also includes one or more standoffs 810 that are provided on the first surface 808 of the semiconductor die 802. As an example, the standoff(s) 810 can be a single standoff that surrounds the precision components 804. A cap 812, such as formed from silicon, can be provided on the standoff(s) 810, such as provide a cavity 814 that surrounds the precision components 804.

The IC package 800 also includes a film 816 patterned over the cap 812. Therefore, the cap 812 and the film 816 overlay the precision components 804. As an example, the film 816 can correspond to any of a variety of photo-patternable polymer films, such as any of a variety of SU-8 materials or polyimide materials. The IC package 800 also includes a substrate 818 to which the semiconductor die 802 is coupled. The substrate 818 can correspond to a metal material frame that can provide connections to ground and to pins of the completed IC chip, such that portions of the substrate can extend from the completed IC chip. The substrate 818 is demonstrated as attached to a second surface 820 of the semiconductor die 802, with the second surface 820 being opposite the first surface 808. An adhesive material 822 (e.g., a die-attach material) can be used to couple the semiconductor die 802 to the substrate 818.

The IC package 800 further includes a molding material 824 that can cover at least the first surface 808 of the semiconductor die 802. As an example, the molding material 824 can fill voids between the components of the IC package 800 and the interior of a chip package (not shown in the example of FIG. 8). As described herein, the material from which the film 816 is formed can be non-adhesive with respect to the molding material 824. Therefore, the molding material 824 can be delaminated with respect to the film 816. In the example of FIG. 8, the delamination is demonstrated as a air gap 826 between the film 816 and the molding material 824. As a result, mechanical stresses on the precision components 804, such as being provided through the molding material 824, can be mitigated based on the air gap between the molding material 824 and the precision components 804, as well as the cavity 814 formed by the standoff(s) 810 and the cap 812.

In view of the foregoing structural and functional features described above, a methodology in accordance with various aspects of the present invention will be better appreciated with reference to FIG. 9. While, for purposes of simplicity of explanation, the methodology of FIG. 9 is shown and described as executing serially, it is to be understood and appreciated that the present invention is not limited by the illustrated order, as some aspects could, in accordance with the present invention, occur in different orders and/or concurrently with other aspects from that shown and described herein. Moreover, not all illustrated features may be required to implement a methodology in accordance with an aspect of the present invention.

FIG. 9 illustrates an example of a method 900 for fabricating an IC package (e.g., the IC package 100). At 902, a semiconductor die (e.g., the semiconductor die 102) comprising an IC is fabricated. The IC can include precision components (e.g., the precision components 104) arranged proximal to a first surface (e.g., the first surface 206) of the semiconductor die. At 904, a film (e.g., the film 106) is patterned over a portion of the first surface of the semiconductor die. The portion of the first surface of the semiconductor die can overlay the precision components. At 906, a second surface (e.g., the second surface 212) of the semiconductor die opposite the first surface is attached to a substrate (e.g., the substrate 210). At 908, molding material (e.g., the molding material 108) is deposited over the semiconductor die to cover at least the first surface of the semiconductor die.

In this description, the term “couple” may cover connections, communications, or signal paths that enable a functional relationship consistent with this description. For example, if device A generates a signal to control device B to perform an action, then: (a) in a first example, device A is directly coupled to device B; or (b) in a second example, device A is indirectly coupled to device B through intervening component C if intervening component C does not substantially alter the functional relationship between device A and device B, so device B is controlled by device A via the control signal generated by device A.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

Modifications are possible in the described embodiments, and other embodiments are possible, within the scope of the claims.

What is claimed is:

1. A method for fabricating an integrated circuit (IC) package, the method comprising:
fabricating a semiconductor die comprising an IC;
patterning a film over a portion of a first surface of the semiconductor die;
attaching a second surface of the semiconductor die opposite the first surface to a substrate; and
depositing molding material over the semiconductor die to cover at least the first surface of the semiconductor die.

2. The method of claim 1, wherein fabricating the semiconductor die comprises fabricating the IC comprising precision components arranged proximal to the first surface of the semiconductor die, wherein patterning the film comprises patterning the film over the portion of the first surface of the semiconductor die overlying the precision components.

3. The method of claim 2, wherein fabricating the semiconductor die comprises etching at least one trench into the first surface of the semiconductor die to at least partially enclose the precision components by the at least one trench.

4. The method of claim 1, wherein the film is formed from a photo-patternable polymer film material.

5. The method of claim 4, wherein the photo-patternable polymer film material is either an SU-8 material or a polyimide material.

6. The method of claim 1, wherein patterning the film comprises performing a photo-patterning process to pattern the film over the portion of the first surface.

7. The method of claim 1, further comprising:
applying a standoff to the first surface of the semiconductor die; and
coupling a first surface of a cap to the standoff, the cap covering the portion of the first surface of the semiconductor die, wherein patterning the film comprises patterning the film on a second surface of the cap opposite the first surface.

8. An integrated circuit (IC) package comprising:
a semiconductor die comprising an IC;
a film patterned over a portion of the first surface of the semiconductor die;
a substrate coupled to a second surface of the semiconductor die opposite the first surface; and
molding material covering at least the first surface of the semiconductor die.

9. The package of claim 8, wherein the IC comprises precision components arranged proximal to a first surface of the semiconductor die, wherein the portion of the first surface of the semiconductor die overlays the precision components.

10. The package of claim 8, wherein the film is formed from a photo-patternable polymer film material.

11. The package of claim 10, wherein the photo-patternable polymer film material is either an SU-8 material or a polyimide material.

12. The package of claim 8, wherein the film is patterned based on a photo-patterning process over the portion of the first surface.

13. The package of claim 8, wherein the semiconductor die comprises at least one trench etched into the first surface of the semiconductor die.

14. The package of claim 13, wherein the at least one trench at least partially encloses the precision components.

15. The package of claim 9, further comprising:
a standoff coupled to the first surface of the semiconductor die; and
a cap coupled to the standoff, the cap covering the portion of the first surface of the semiconductor die.

16. The package of claim 15, wherein the cap is coupled to a first surface of the standoff, wherein the film is patterned on a second surface of the cap opposite the first surface.

17. An integrated circuit (IC) package comprising:
a semiconductor die comprising an IC, the IC comprising precision components arranged proximal to a first surface of the semiconductor die;
a photo-patternable polymer film photo-patterned over a portion of the first surface of the semiconductor die, the portion of the first surface of the semiconductor die overlying the precision components;
a substrate coupled to a second surface of the semiconductor die opposite the first surface; and
molding material covering at least the first surface of the semiconductor die.

18. The package of claim 17, wherein the photo-patternable polymer film is formed from either an SU-8 material or a polyimide material.

19. The package of claim 17, wherein the semiconductor die comprises at least one trench etched into the first surface of the semiconductor die, the at least one trench at least partially enclosing the precision components.

20. The package of claim 17, further comprising:
a standoff coupled to the first surface of the semiconductor die; and
a cap coupled to a first surface of the standoff and covering the portion of the first surface of the semiconductor die, wherein the photo-patternable polymer film is patterned on a second surface of the cap opposite the first surface.
